(19) United States
(12) Patent Application Publication
(10) Pub. No.: US 2025/0220947 A1
(43) Pub. Date: Jul. 3, 2025

(54) HEMT Device with Unmetallized Gate

(71) Applicant: TEXAS INSTRUMENTS INCORPORATED, Dallas, TX (US)

(72) Inventor: Dong Seup Lee, McKinney, TX (US)

(21) Appl. No.: 18/397,453

(22) Filed: Dec. 27, 2023

(51) Int. Cl. H01L 29/778; H01L 29/20; H01L 29/423; H01L 29/66

(52) U.S. Cl. CPC H10D 30/475; H10D 30/015; H10D 62/8503; H10D 64/519

(57) ABSTRACT

An integrated circuit includes a first III-N material layer, and a different second III-N material layer supported by the first III-N material layer. A p-doped III-N material layer over the second III-N material layer includes a wider portion having a first width in a first lateral direction parallel to the top surface, and a narrower portion extending from the wider portion in a different second lateral direction parallel to the top surface, the narrower portion having a second width in the first lateral direction less than the first width.

### FIELD

This disclosure relates to the field of semiconductor devices, and more particularly, but not exclusively, to integrated circuits including GaN-based transistor devices.

### BACKGROUND

Gallium nitride (GaN) field-effect transistors (FETs), sometimes referred to as high-electron-mobility transistors (HEMTs), offer weight, size, cost, switching-speed, and energy-consumption advantages over silicon FETs, and are used in such applications as 5G rectifiers, motor drives, and AC-to-DC power converters as may be used to power portable computers and charge mobile device batteries. GaN devices come in enhancement mode (e-GaN) and depletion mode (d-GaN) types. Whereas a depletion-mode device is normally on when its gate-source voltage is zero, an enhancement-mode FET is normally off when its gate-source voltage is zero. An enhancement-mode FET can be turned on by maintaining the gate voltage to be more than the source voltage in NMOS circuits and less than the source voltage in PMOS circuits. Enhancement-mode FETs are commonly used as power switches.

### SUMMARY

The inventor discloses various methods and devices that may be beneficially applied to GaN-based FET devices and systems employing such devices. While such embodiments may be expected to provide various benefits in various use applications, no particular result is a requirement of the present invention unless explicitly recited in a particular claim.

One example is an integrated circuit that includes a first III-N material layer, and a different second III-N material layer supported by the first III-N material layer. A p-doped III-N material layer over the second III-N material layer includes a wider portion having a first width in a first lateral direction parallel to the top surface, and a narrower portion extending from the wider portion in a different second lateral direction parallel to the top surface, the narrower portion having a second width in the first lateral direction less than the first width.

Another example is a transistor including a gallium nitride (GaN) layer and an aluminum-gallium nitride (AlGaN) layer on the GaN layer. Source and drain contacts are spaced apart along a top surface of the AlGaN layer. A p-doped GaN (p-GaN) layer is located on the AlGaN layer and includes a metalized gate terminal portion and an unmetalized gate drive portion extending from the gate terminal portion between the source and drain contacts.

Other examples include methods of manufacturing devices as described above.

### BRIEF DESCRIPTION OF THE VIEWS OF THE DRAWINGS

FIGS. 1A-1C illustrate views of an example electronic device including a gate electrode having a terminal portion and a drive portion extending from the terminal portion;

FIGS. 2A-2D illustrate various example configurations of gate electrodes having a terminal portion and a drive portion;

FIG. 3 is a plot showing drive current (I_{dsat}) of a four populations of manufactured transistors, each population having one of four different gate lengths; and

FIG. 4 is a plot showing threshold voltage (V_{T}) of the four populations of manufactured transistors shown in FIG. 3; and

FIGS. 5A-C through FIGS. 11A-11C illustrate aspects of forming an example electronic device according to the principles of the disclosure.

### DETAILED DESCRIPTION

The present disclosure is described with reference to the attached figures. The figures are not necessarily drawn to scale, and they are provided without implied limitation to illustrate various described examples. Several aspects of the disclosure are described below with reference to example applications for illustration. It should be understood that numerous specific details, relationships, and methods are set forth to provide an understanding of the disclosure. The present disclosure is not limited by the illustrated ordering of acts or events unless stated otherwise, as some acts may occur in different orders and/or concurrently with other acts or events. Furthermore, all illustrated acts or events may not be required to implement a methodology in accordance with the present disclosure.

This disclosure presents various methods and devices that may be beneficially applied to integrated circuits including GaN or other III-N field effect transistors (FETs) with narrow gate lengths. While such embodiments may be expected to support scaling of transistor designs to dimensions that do not easily accommodate current strategies to mitigate gate leakage, no particular feature or result is a requirement unless explicitly recited in a particular claim.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

HEMT transistors may operate on the principle of modulating the conductivity in a portion of a two-dimensional electron gas (2DEG) formed by spontaneous polarization at an interface between dissimilar compound semiconductors, e.g. between aluminum gallium nitride (AlGaN) and gallium nitride (GaN). In some baseline HEMTs, a gate structure includes a gate drive portion that is substantially metalized. For example, such a device may include a p-GaN gate over an AlGaN layer. Such baseline devices typically include a metal layer over the p-GaN gate. The metal layer may form a Schottky capacitance C_{schottky}, between the metal layer and the p-GaN gate, and the p-GaN gate may form a capacitance C_{AlGaN} between the p-GaN gate and the underlying AlGaN layer. In typical baseline devices the metal layer extends nearly to an edge of the p-GaN gate to maximize C_{schottky}. If the metal layer extends to close to the edge of the p-GaN gate, excessive leakage from them metal layer to the AlGaN layer may occur, degrading the performance of the transistor. Conversely, if the metal layer is too far from the edge of the p-GaN gate then C_{schottky} may be reduced, thereby reducing capacitive coupling to the AlGaN layer. This reduction may reduce the effectiveness of the p-GaN gate to control current flow through the of transistor.

The inventor has discovered that with appropriate device design, the metal layer may be omitted from drive portion of the p-GaN gate structure. In spite of resistance of the drive portion, one or more metalized gate terminal portions directly connected to the drive portion may suffice to control the channel conductance of the transistor, thereby obviating issues related to gate metallization leakage. Devices formed according to such principles and consistent with examples described herein may have a shorter gate length than analogous baseline devices while eliminating performance variation between devices that could otherwise exist due to manufacturing variation.

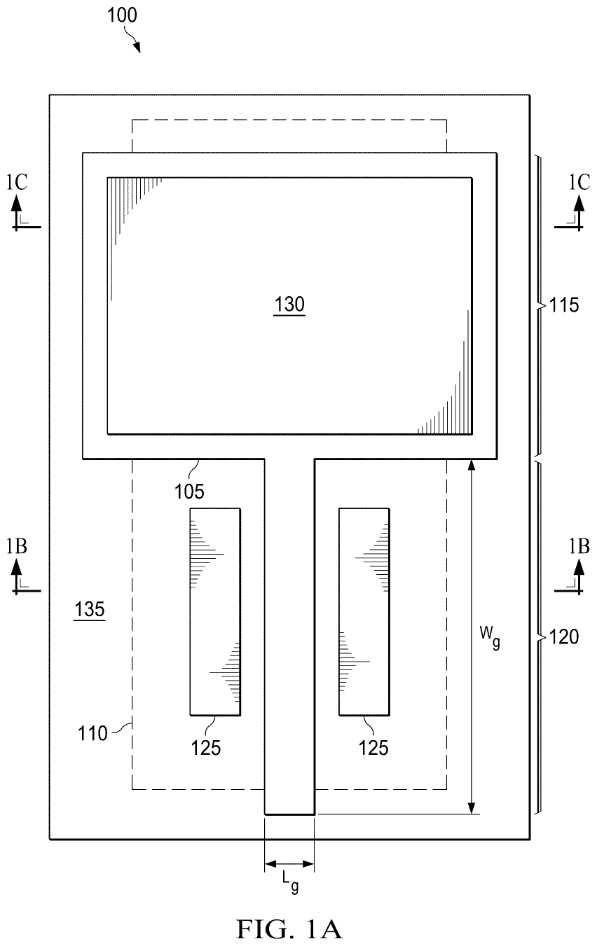

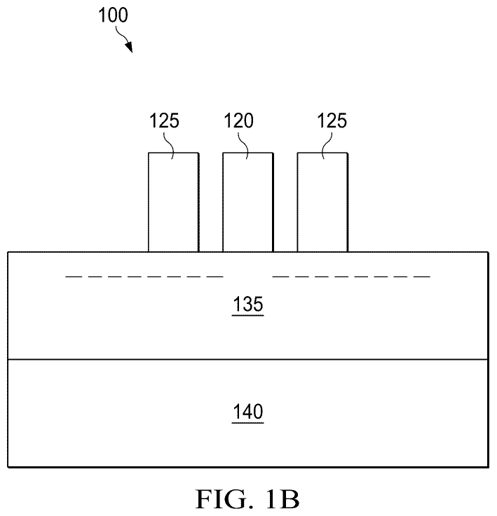

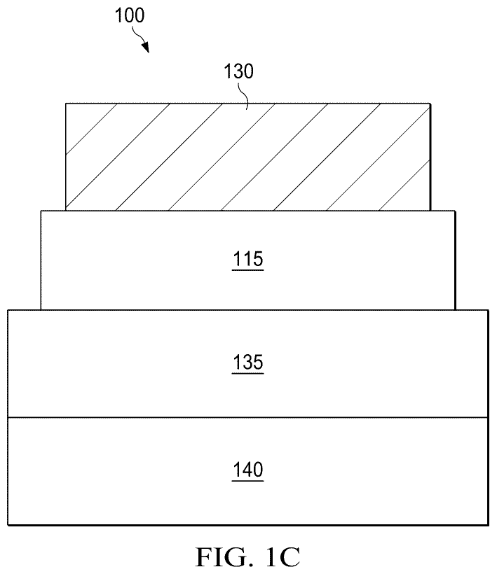

FIGS. 1A-1C present views of an example transistor 100 according to various aspects of the disclosure. FIG. 1A is a plan view of the transistor 100, and FIGS. 1B and 1C are section views taken at two locations along the transistor 100, as marked in FIG. 1A. Note that features in FIGS. 1B and 1C are not necessarily drawn at the same scale as the same features in FIG. 1A. Referring initially to FIG. 1A, the transistor includes a gate electrode 105 over an active area 110. The gate electrode 105 includes a wider gate terminal portion 115 and a narrower gate drive portion 120. Herein, “drive portion” and similar terms refer to the portion of the gate electrode 105 located over a channel region of the transistor 100, e.g. that portion of the transistor 100 through which current flows when the transistor 100 is appropriately configured. In accordance with common transistor nomenclature, the gate drive portion 120 has a gate length L_{g} and a gate width W_{g}. The gate drive portion 120 extends from the gate terminal portion 115 between a pair of source/drain (S/D) contacts 125. The gate terminal portion 115 is metalized, having a metal layer 130 located thereover (FIGS. 1A and 1C). In contrast, the gate drive portion 120 is not metalized, thus having no metal layer formed thereover.

The transistor 100 is an enhancement-mode, or “e-mode” transistor. For such a device, a gap in a 2DEG (indicated by dashed lines in FIG. 1B) is formed under the gate drive portion 120, rendering the transistor 100 nonconductive, or off, in the absence of a bias voltage applied to the gate electrode 105. Note that the 2DEG is also suppressed under the gate terminal portion 115.

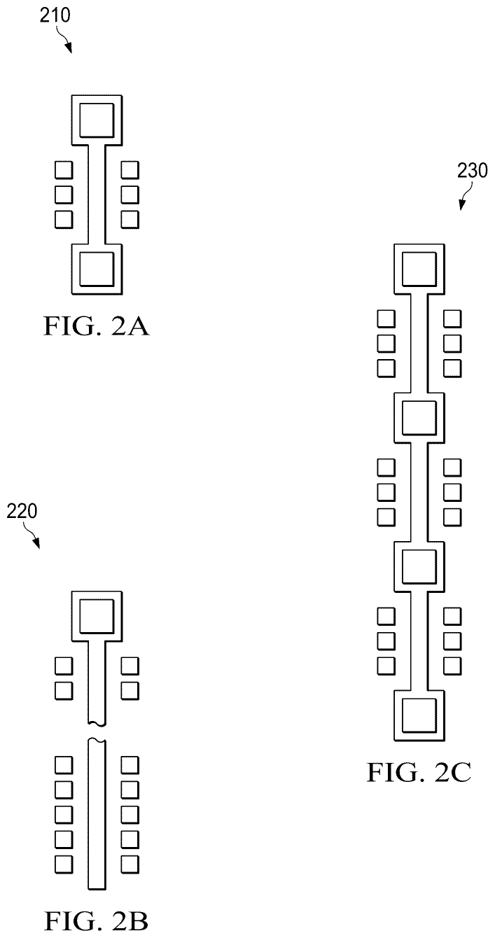

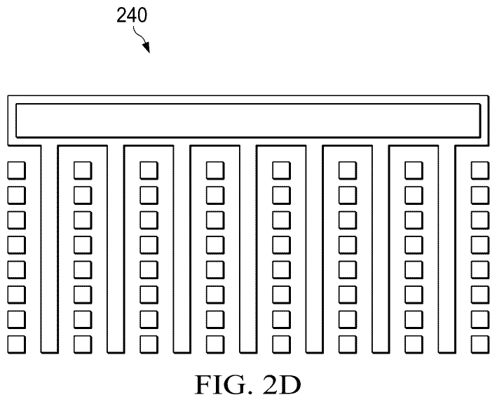

FIGS. 2A-2D illustrate various configurations of HEMT gates according to the disclosure. FIG. 2A shows a “dog bone” configuration 210, in which a gate drive portion extends between one or more (e.g. three) pairs of source/drain contacts from a first gate terminal portion to a second gate terminal portion. FIG. 2B shows a second configuration 220 in which the gate drive portion extends from only a single gate terminal portion, such as exemplified in FIG. 1A. FIG. 2C illustrates a configuration 230 that includes multiple, at least three, gate terminal portions spaced apart in linear fashion, with a gate drive portion extending from each gate terminal portion to a nearest-neighbor gate terminal portion. And FIG. 2D illustrates an example configuration 240 in which multiple gate drive portions extend in parallel from a single gate terminal portion. Each of the example configurations 210, 220, 230 and 240 may include any number of source/drain contacts determined to meet the performance specifications for that device. It is expected that in various examples the gate drive portion may extend as much as at least 10 μm from a gate terminal portion (or 20 μm between two gate terminal portions) without significant degradation of transistor performance parameters due to, e.g. gate material resistivity.

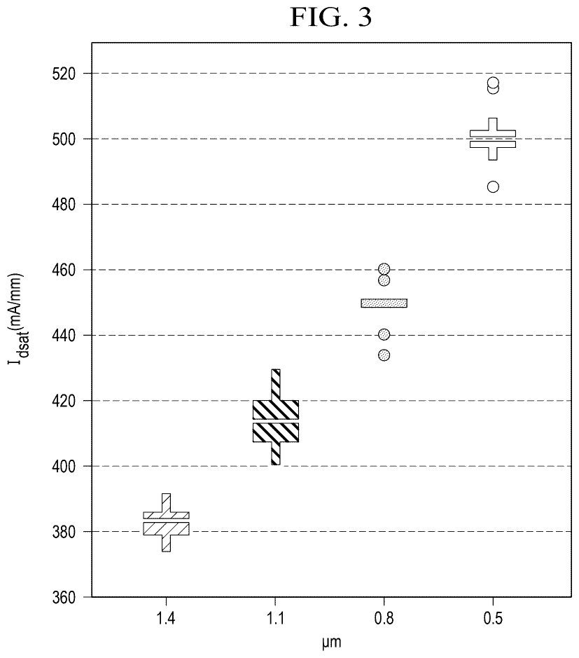

FIG. 3 presents a series of box-plots of saturation current I_{Dsat} for example devices consistent with the configuration 210, e.g. having no metal over the gate in the active area of the transistors, with a gate width of about 13 μm. Four different populations of devices are shown, having a gate length of 1.4 μm, 1.1 μm, 0.8 μm, and 0.5 μm. This figure shows that I_{dsat} scales about linearly with decreasing gate width, indicating effective coupling between the gate and the underlying AlGaN layer despite the lack of metallization on the gate.

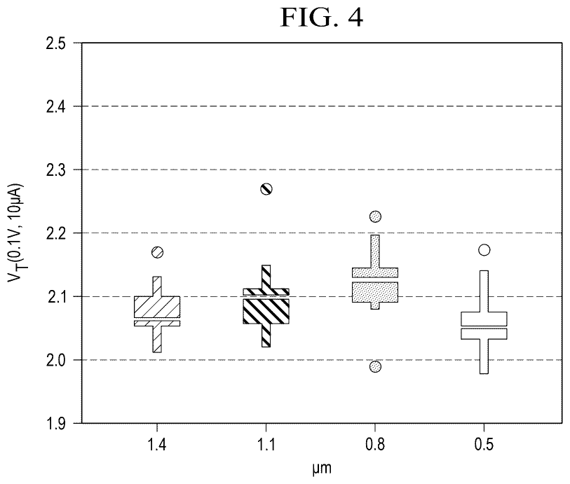

FIG. 4 presents a series of box-plots of threshold voltage V_{T} for the example devices represented in FIG. 3. This figure shows that V_{T} is approximately constant over the example range of gate lengths, indicating consistent operating voltage and viability for use in circuits that would otherwise use a metalized gate structure.

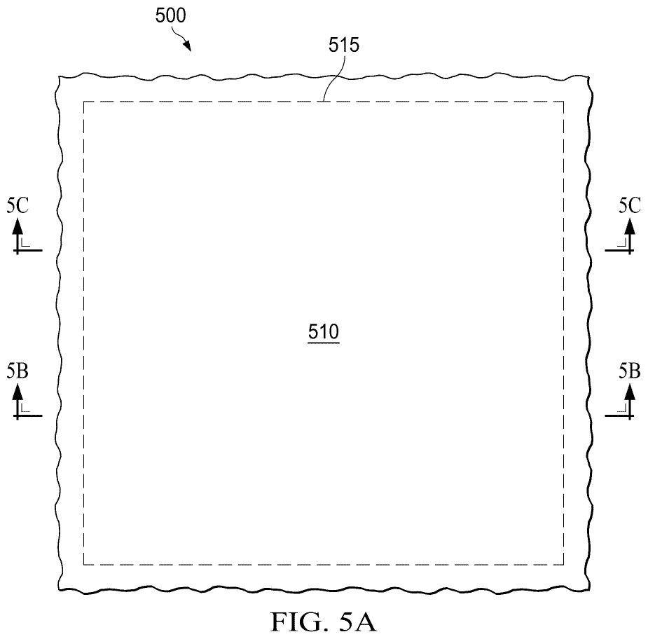

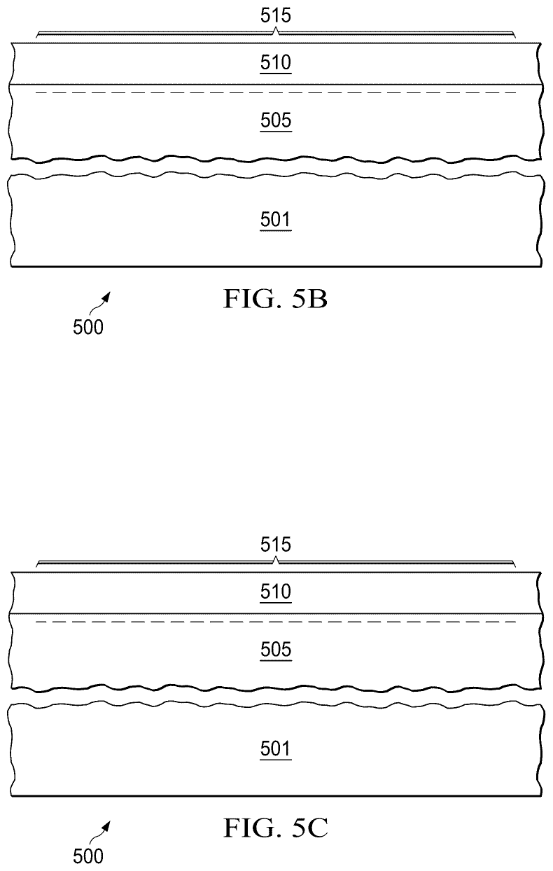

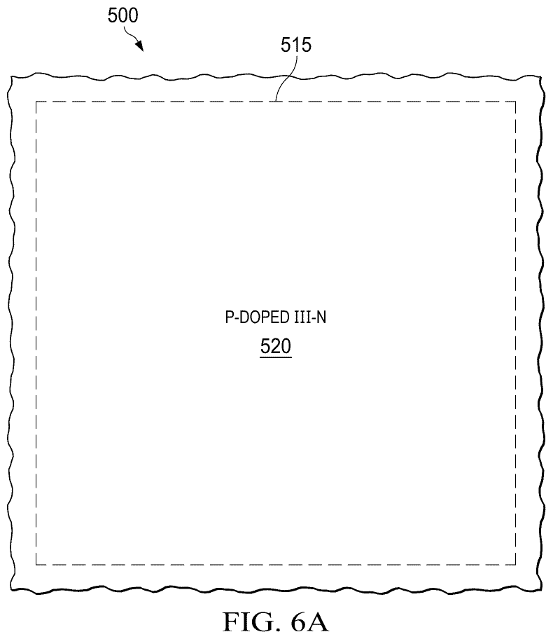

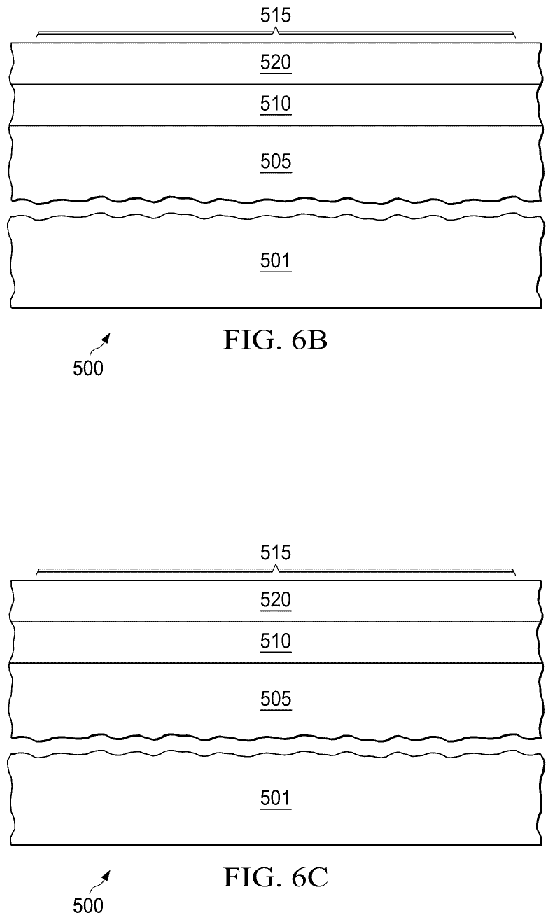

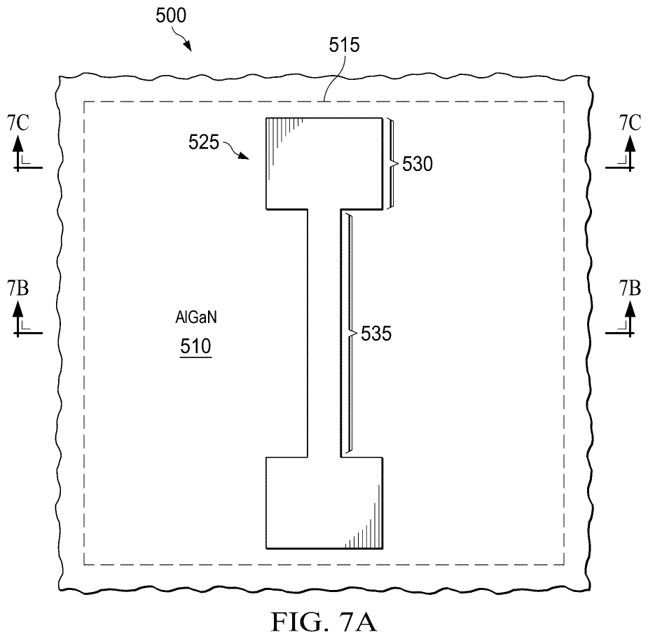

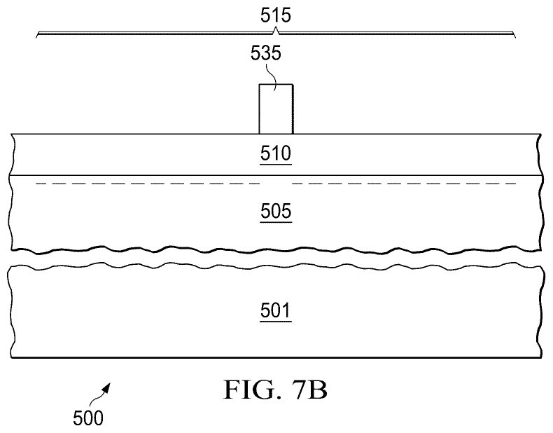

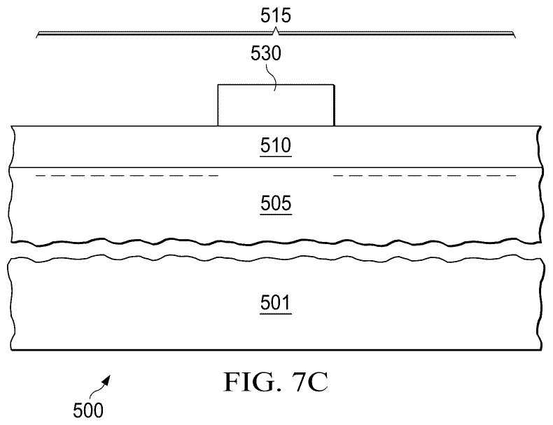

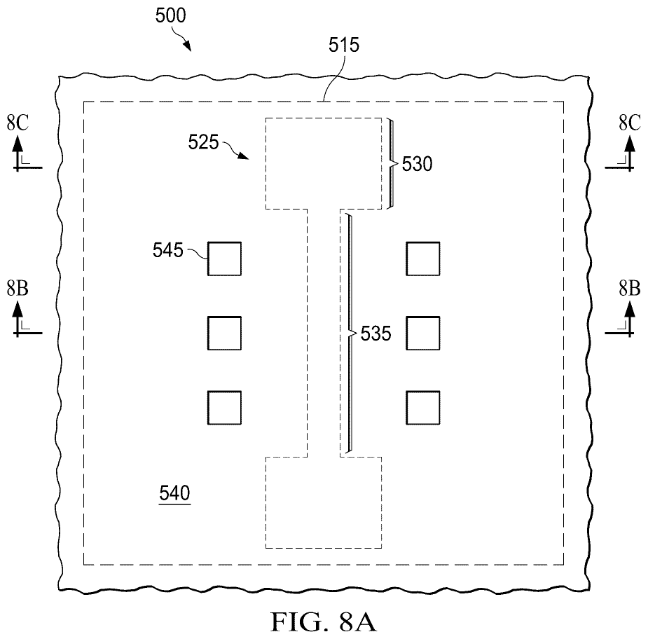

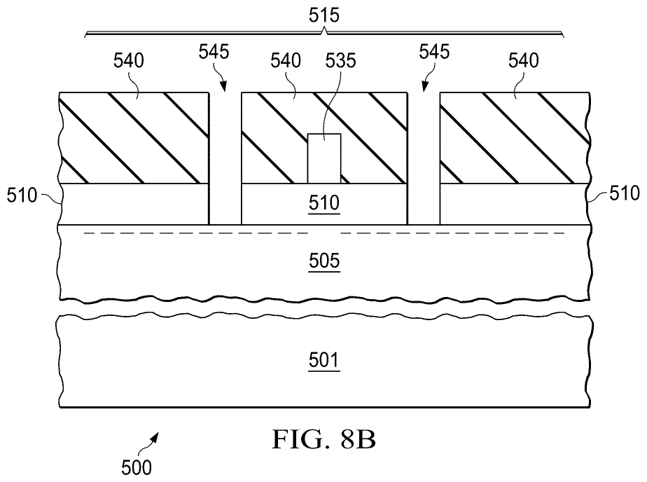

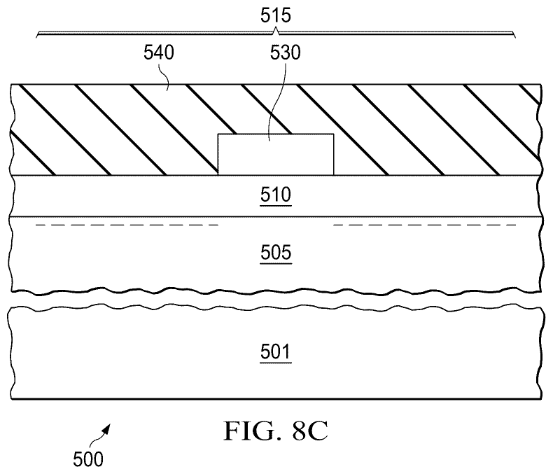

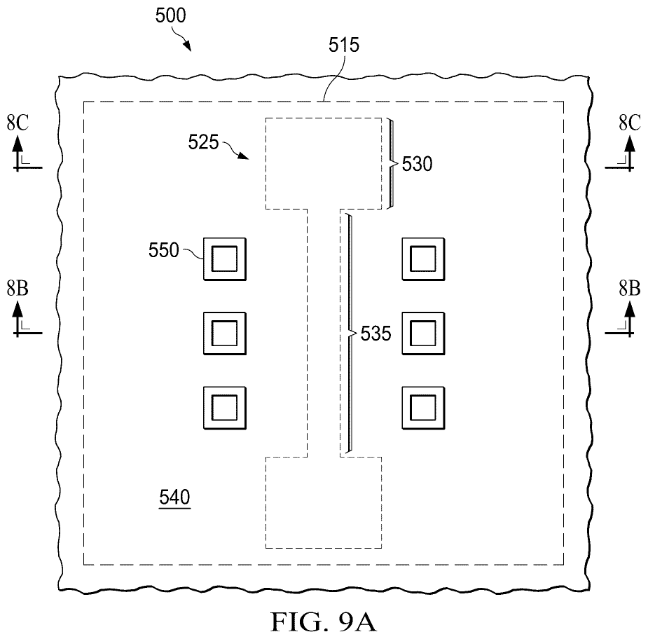

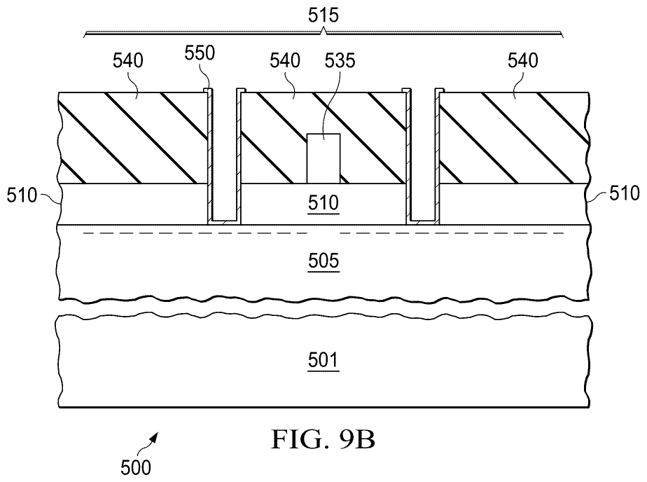

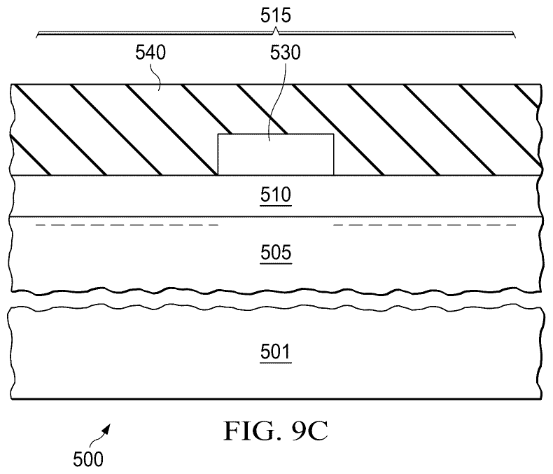

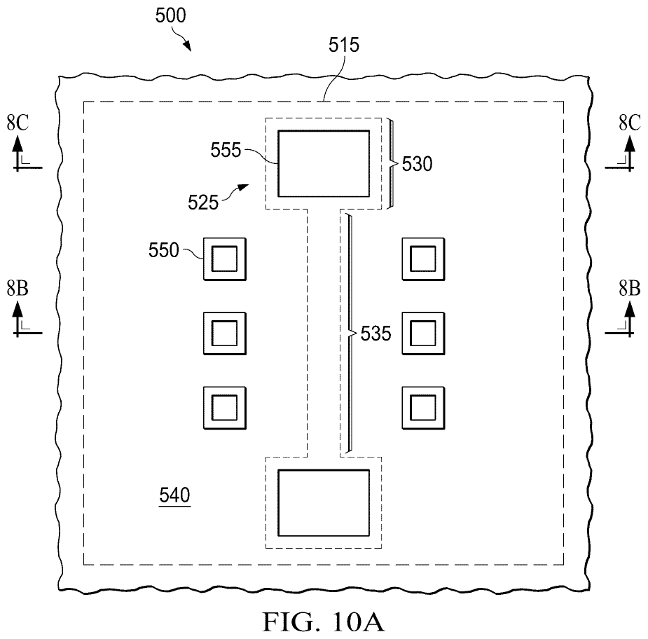

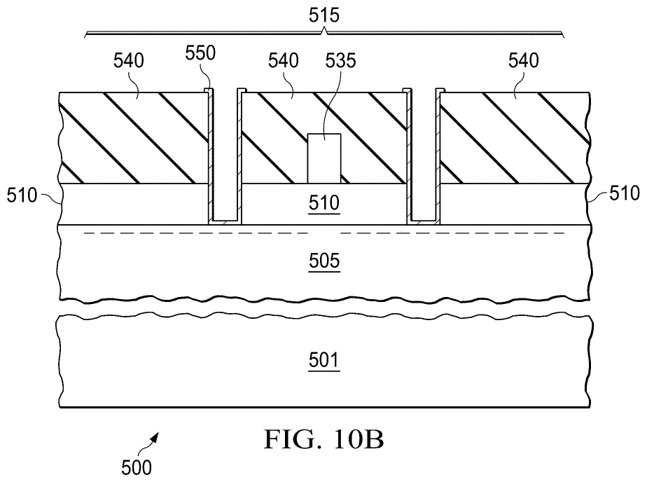

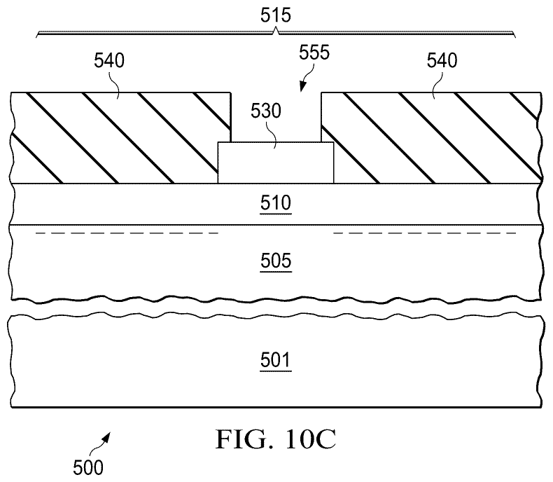

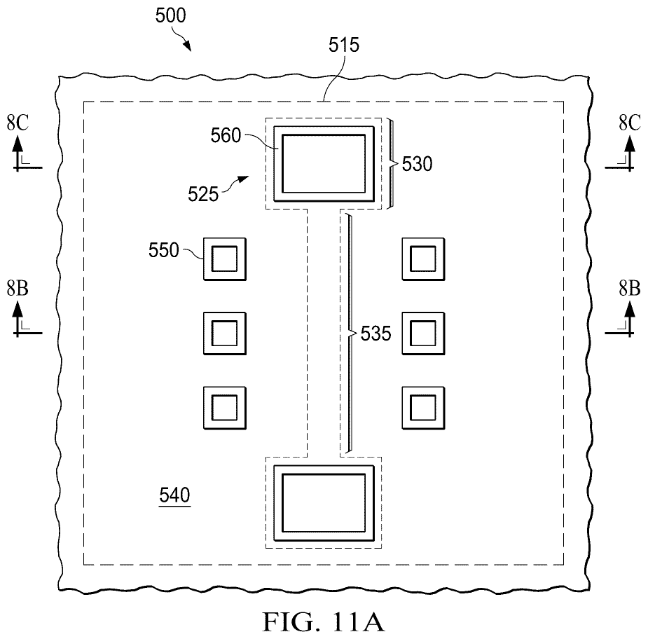

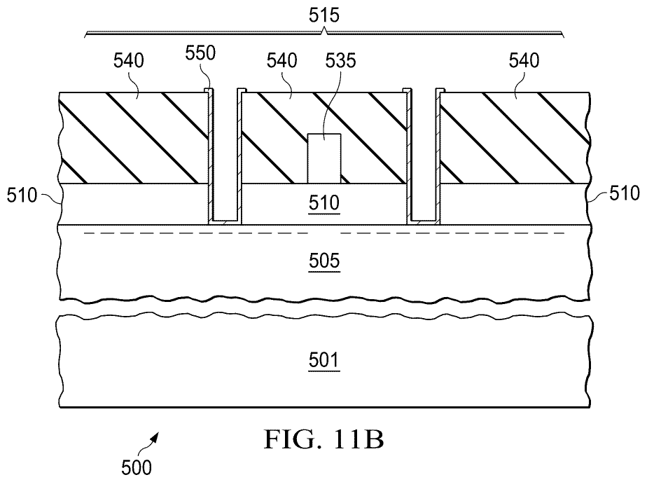

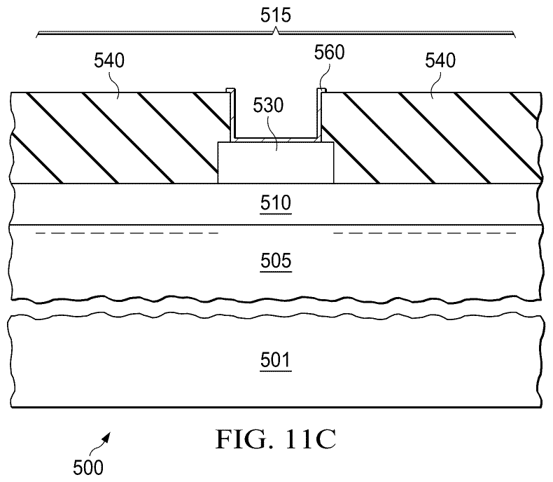

Turning now FIGS. 5A-5C through 11A-11C, an example method of making an integrated circuit (IC) is described, the integrated circuit including a transistor 500 consistent with the transistor 100 and the example configurations 210-240. In some examples, and as illustrated, the transistor 500 is an e-mode transistor. FIGS. 5A-11A illustrate a plan view of the transistor 500, FIGS. 5B-11B show a first section view as marked in the corresponding plan view, and FIGS. 5C-11C show a second section view as marked in the corresponding plan view. Each set of corresponding figures may be described concurrently unless further distinguishing among the figures is needed for clarity.

FIGS. 5A-5C illustrate the transistor 500 at an early stage of manufacturing. A substrate 501 supports a first compound semiconductor layer 505 and a second compound semiconductor layer 510. A 2DEG represented as a dashed line is formed in the layer 505 near the interface with the layer 510. While in various examples the layers 505 and 510 may be respectively implemented as a GaN layer and an AlGaN layer, or any two semiconductor materials that form a 2DEG at a mutual interface. In this context the layer 510 may be considered a barrier layer. Such semiconductor materials may generally be referred to as “III-N” materials, and include one or more elements from group III of the periodic table (e.g. Al, Ga and In) and nitrogen. In addition to GaN and AlGaN, other III-N materials include compounds with the general empirical formula In(x)Al(y)Ga(1-x-y)N, non-limiting examples including InAlN, AlN and InAlGaN). In the remaining discussion the layer 505 may be referred to as “first III-N layer 505” and the layer 510 may be referred to as “second III-N layer 510”. The 2DEG is located within an active area 515. Outside the active area the 2DEG may be disrupted or destroyed by an amorphizing implant, such as argon (Ar) or other non-doping ion species. The active area 515, analogous to the active area 110 (FIG. 1A), defines a lateral perimeter of the transistor 500. Not shown explicitly are a number of stress compensation layers between the substrate 501, which may be a silicon wafer or die, and the first III-N layer 505. Such stress compensation layers are well-known in the art and are thus not described in greater detail.

FIGS. 6A-6C illustrate the transistor 500 after formation of a doped semiconductor layer 520 over the second III-N layer 510. Consistent with forming e-mode device, the semiconductor layer 520 is doped p-type, for example being doped with magnesium (Mg). Such a material may be generally referred to as a “p-doped III-N” material. In the remaining discussion the layer 520 may be referred to as “p-doped III-N layer 520” The presence of the p-doped III-N layer 520 quenches the 2DEG in the active area 515, reflected by the absence of the dashed line at the interface between the first III-N layer 505 and the second III-N layer 510. Not shown, a dielectric passivation layer, such as a thin layer of SiN, may be formed over the p-doped III-N layer 520.

Referring next to FIGS. 7A-7C, a gate structure 525 is formed by patterning and removing a portion of the p-doped III-N layer 520. The gate structure 525 has a shape that may be colloquially referred to as a “dog bone” shape, and two wider gate terminal portions 530 having a first width in a first lateral direction parallel to a top surface of the second III-N layer 510, and a narrower gate drive portion 535 that extends from one gate terminal portion 530 to the other gate terminal portion 530, the gate drive portion 535 having a second width in the first lateral direction less than the first width. As illustrated in FIGS. 7B and 7C, removal of the p-doped III-N layer 520 allows the 2DEG at the interface between the second III-N layer 510 and the first III-N layer 505 to reform, but the 2DEG is absent beneath the gate terminal portions 530 and the gate drive portions 535.

FIGS. 8A-8C show the transistor 500 after forming over the gate structure 525 a dielectric layer 540 that may be or include, e.g. SiN. A top surface of the dielectric layer 540 may be planarized, e.g. by CMP, if topography of the top surface is undesirable. Source/drain contact openings 545 have been formed by lithographic patterning and etch, resulting in three pairs of source/drain contact openings 545 in one non-limiting example that extend to the top surface of the first III-N layer 505.

In FIGS. 9A-9C, contact liners 550 have been formed within the source/drain contact openings 545 (FIGS. 9A and 9B). The contact liners 550 directly contact the first III-N layer 505 and form ohmic contacts to the 2DEG. In one non-limiting example, the contact liners 550 may include a first sub-layer of Ti, followed by AlCu, TiN and W. These conductive layers may be formed by physical vapor deposition (PVD) and/or chemical vapor deposition (CVD) techniques.

FIGS. 10A-10C illustrate the transistor 500 after forming gate contact openings 555 (FIGS. 10A and 10C) over the gate terminal portions 530. The gate contact openings may be formed by lithographic patterning and etch to remove the dielectric layer 540 over the gate terminal portions 530. While the size of the gate contact openings 555 is not limited to any particular value, they may have a lateral extent about equal to the lateral extent of the gate terminal portions 530, with the exception of a small annular offset consistent with reducing leakage between a later-formed metal gate terminal contact and the second III-N layer 510.

FIGS. 11A-11C illustrate the transistor 500 after forming gate contacts 560 over gate terminal portions 530 (FIGS. 11A and 11C). The gate contacts 560 may be implemented by a layer of TiW to provide a conductive connection to the gate terminal portions 530 and a later-formed metal interconnect. Additional processing may be performed as needed to connect the transistor 500 to other devices of the integrated circuit. Note that process sequences other than that shown are within the scope of the disclosure, for example forming the gate contacts 560 prior to forming the contact liners 550. Additional background is described in United States Patent Application No. 2022/0399328A, incorporated herein by reference in its entirety.

Contrary to analogous baseline transistors, the metal layer from which the gate contacts 560 are formed does not extend over the gate drive portion 535. The omission of the metallization over the gate drive portion 535 obviates the possibility of leakage from such metallization that could otherwise exist, simplifying device scaling to dimensions that do not easily accommodate design layer.

1. An integrated circuit (IC), comprising:
a first III-N material layer;
a different second III-N material layer supported by the first III-N material layer, the second III-N material layer having top surface; and
a p-doped III-N material layer over the top surface of the second III-N material layer, the p-doped III-N material layer including a wider portion having a first width in a first lateral direction parallel to the top surface, and a narrower portion extending from the wider portion in a different second lateral direction parallel to the top surface, the narrower portion having a second width in the first lateral direction less than the first width.

2. The IC of claim 1, further comprising a metal layer on the p-doped III-N material layer, the metal layer confined to the wider portion.

3. The IC of claim 1, wherein the narrower portion is located between first and second ohmic contacts to the second III-N material layer.

4. The IC of claim 1, wherein the wider portion is a first wider portion, and further comprising a second wider portion, the narrower portion extending from the first wider portion to the second wider portion.

5. The IC of claim 1, wherein the narrower portion is a first narrower portion, and further comprising a second narrower portion extending from the wider portion in the second lateral direction.

6. The IC of claim 1, wherein the second III-N material layer comprises AlGaN.

7. The IC of claim 6, wherein the p-doped III-N material layer comprises GaN.

8. A transistor, comprising:
a gallium nitride (GaN) layer;
an aluminum-gallium nitride (AlGaN) layer on the GaN layer;
source and drain contacts spaced apart along a top surface of the AlGaN layer; and
a p-doped GaN (p-GaN) layer on the AlGaN layer, the p-GaN layer including a metalized gate terminal portion and an unmetalized gate drive portion, the gate drive portion extending from the gate terminal portion between the source and drain contacts.

9. The transistor of claim 8, wherein the gate terminal portion has a first width in a lateral direction parallel to the top surface, and the gate drive portion has a smaller second width in the lateral direction.

10. The transistor of claim 8, wherein the gate drive portion extends between a plurality of pairs of source and drain contacts.

11. The transistor of claim 8, wherein the metallized gate terminal portion is a metallized first gate terminal portion, and the gate drive portion extends from the first metallized gate terminal portion to a second metallized gate terminal portion.

12. The transistor of claim 8, wherein the gate drive portion is a first gate drive portion, and further comprising a second gate drive portion extending from the gate terminal portion.

13. The transistor of claim 11, wherein the gate terminal portion is a first gate terminal portion, and a second gate drive portion extends from the second gate terminal portion to a third gate terminal portion.

14. The transistor of claim 8, wherein the gate drive portion has a length of at least about 10 μm.

15. A method of forming an integrated circuit, comprising:
forming a gallium nitride (GaN) layer over a semiconductor substrate;
forming an AlGaN layer on the GaN layer; and
forming a p-doped GaN (p-GaN) layer on the AlGaN layer, the p-GaN layer including a gate terminal portion having a first width in a lateral direction and a gate drive portion having a second width in the lateral direction extending from the gate terminal portion, the first width greater than the second width.

16. The method of claim 15, further comprising masking the gate drive portion and forming a metal layer on the gate terminal portion.

17. The method of claim 15, further comprising forming first and second ohmic contacts to the AlGaN layer, the gate drive portion extending between the first and second ohmic contacts.

18. The method of claim 15, wherein the gate terminal portion is a first gate terminal portion, and further comprising forming a second gate terminal portion spaced apart from the first gate terminal portion, the gate drive portion extending from the first gate terminal portion to the second gate terminal portion.

19. The method of claim 18, further comprising forming a third gate terminal portion spaced apart from the second gate terminal portion, and forming a second gate drive portion that extends from the second gate terminal portion to the third gate terminal portion.

20. The method of claim 15, wherein the gate drive portion is a first gate drive portion, and further comprising forming a second gate drive portion extending from the gate terminal portion.
